(19) United States
(12) Patent Application Publication
(10) Pub. No.: US 2026/0215299 A1
(43) Pub. Date: Jul. 23, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Yu-Chen Hu, Hsinchu City (TW); Hung-Yi Kuo, Taipei City (TW); Yu-Min Liang, Taoyuan City (TW); Hao-Yi Tsai, Hsinchu City (TW)

(73) Assignee: Taiwan Semiconductor Manufacturing Company, Ltd., Hsinchu (TW)

(21) Appl. No.: 19/034,372

(22) Filed: Jan. 22, 2025

(51) Int. Cl. H01L 23/498

(52) U.S. Cl. CPC H10W 70/635; H10W 70/65; H10W 90/701

(57) ABSTRACT

A package structure and a method of forming the same are provided. The package structure includes a circuit substrate, an interposer disposed on and electrically connected the circuit substrate, and a die disposed on the interposer and electrically connected to the circuit substrate through the interposer. The circuit substrate includes a first film stack structure, a second film stack structure disposed on the first film stack structure, and a core structure disposed between the first and second film stack structures. The core structure includes a first semiconductor substrate penetrated by first through semiconductor vias (TSVs). The first TSVs are electrically connected to the first and second film stack structures.

### BACKGROUND

The reliability of a circuit substrate of a package structure has great impact on the performance of the package structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are schematic cross-sectional views and top views of stages in a formation method of a circuit substrate in accordance with some embodiments of the present disclosure.

FIG. 1G is a schematic cross-sectional view of a package structure in accordance with some embodiments of the present disclosure.

FIG. 2A to FIG. 2G are schematic cross-sectional views and top views of stages in a formation method of a circuit substrate in accordance with some embodiments of the present disclosure.

FIG. 2H is a schematic cross-sectional view of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package structure and a method of forming the package structure are provided. The package structure includes a circuit substrate including a core structure sandwiched between first and second film stack structures. The core structure includes a semiconductor substrate (e.g. a silicon-containing semiconductor substrate) penetrated by through semiconductor vias (TSVs). The package structure is supported by the thinner core structure with the excellent mechanical properties of the semiconductor substrate. The thinner core structure is beneficial to the electrical performance such as the Power Delivery Network (PDN) performance. Also, the semiconductor substrate improves the heat dissipation of the package structure. As a result, the reliability of the circuit substrate is improved. Further, passive devices fabricated in the semiconductor substrate improves both the signal integrity and the power integrity. In accordance with some embodiments of the present disclosure, embodiments discussed herein are to provide examples to enable making or using the subject matter of this disclosure, and a person having ordinary skill in the art will readily understand modifications that can be made while remaining within contemplated scopes of different embodiments.

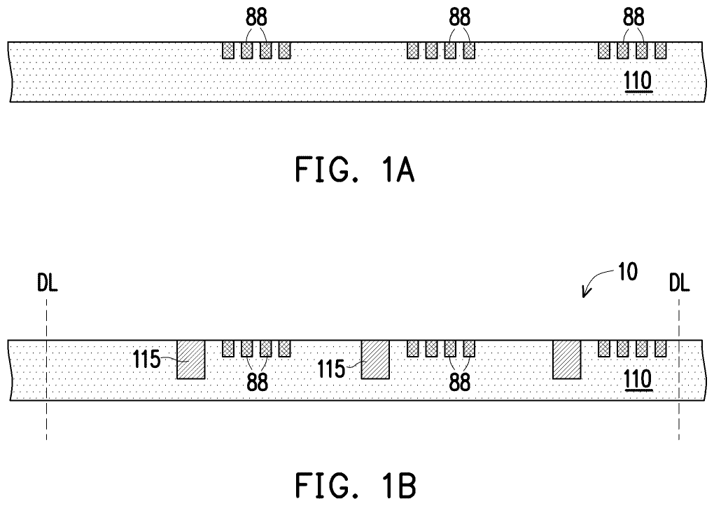

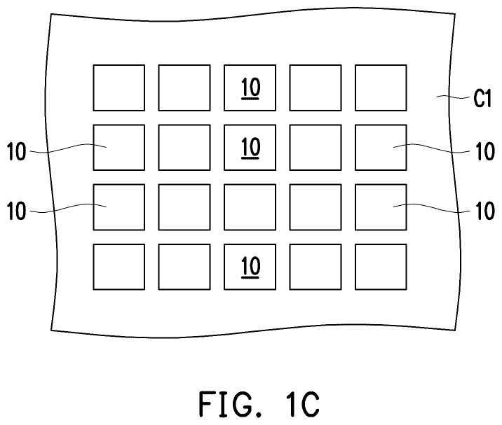

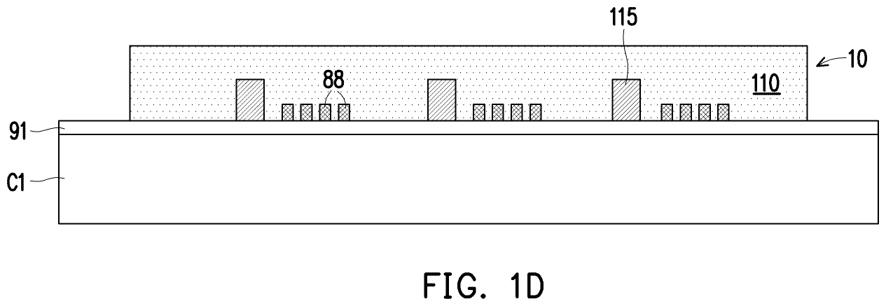

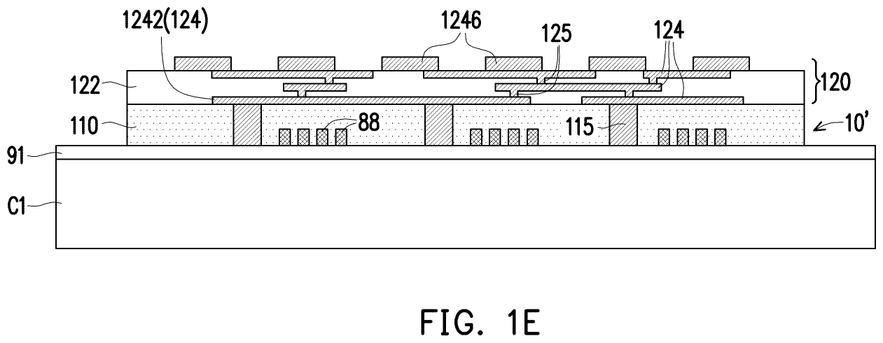

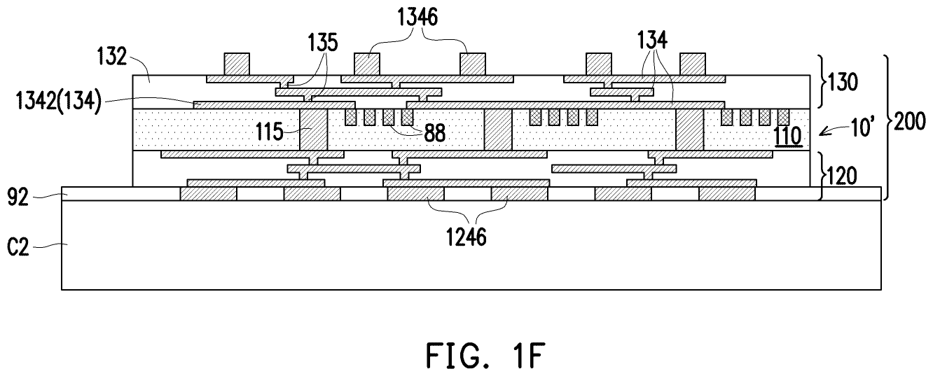

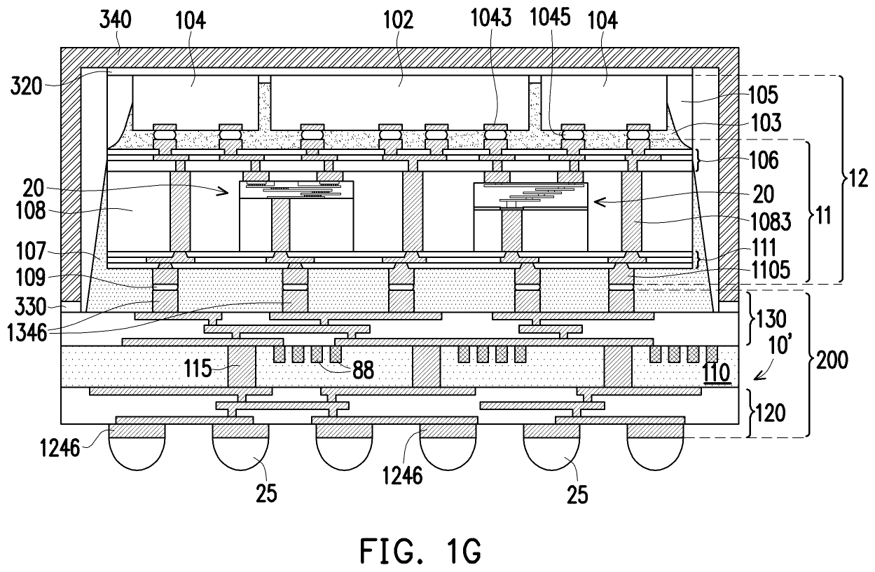

FIG. 1A to FIG. 1F are schematic cross-sectional views and top views of stages in a formation method of a circuit substrate in accordance with some embodiments of the present disclosure.

Referring to FIG. 1A, electronic components 88 are formed in a semiconductor substrate 110. In some embodiments, electronic component 88 is partially formed in the semiconductor substrate 110 and partially formed on the semiconductor substrate 110. For example, the semiconductor substrate 110 (referred to as a silicon-containing semiconductor substrate) is a semiconductor wafer, such as a silicon wafer. In other embodiments, the semiconductor substrate 110 is a silicon carbide (SiC) substrate. In some embodiments, the electronic components 88 includes passive devices such as capacitors (e.g. embedded deep trench capacitors, eDTCs), resistors, inductors, or the like.

Referring to FIG. 1B, metallic vias 115 are formed in the semiconductor substrate 110 and beside the electronic components 88, and extend into the semiconductor substrate 110. In some embodiments, the formation of the metallic vias 115 includes forming openings extending into the semiconductor substrate 110 using acceptable photolithography and etching techniques, such as dry etching. Later, a metallic material is formed inside the openings to fill up the openings, thereby the metallic vias 115 are formed. In some embodiments, the deposition of the metallic material includes performing a plating process. For example, the conductive metallic material includes a metal or a metal alloy, including copper, silver, gold, tungsten, cobalt, aluminum, alloys thereof, or combinations thereof.

In some embodiments, an isolation liner (not shown) is sandwiched between the metallic vias 115 and the semiconductor substrate 110. In some embodiments, the isolation liner is conformally deposited in the openings prior to forming the conductive metallic material. For example, a material of the isolation liner includes a dielectric material, such as silicon oxide (SiO₂). In some embodiments, the isolation liner is formed by using chemical vapor deposition (CVD), atomic layer deposition (ALD), or the like. In some embodiments, a barrier layer (not shown) is sandwiched between the metallic vias 115 and the isolation liner. In some embodiments, the barrier layer is conformally deposited in the openings after forming the isolation liner and before forming the conductive metallic material. For example, a material of the barrier layer includes a metal, such as titanium (Ti), tantalum (Ta), or the like. In some embodiments, the barrier layer is formed by using physical vapor deposition (PVD), or the like.

After the formation of the metallic vias 115, a singulation process is performed to the semiconductor substrate 110 (in wafer form), cutting through the semiconductor substrate 110. In some embodiments, the singulation process includes performing a wafer dicing process cutting along dicing lines DL to form substrate units 10, as shown in FIG. 1C.

Referring to FIG. 1C, FIG. 1C is a top view. The substrate units 10 are provided and disposed on a carrier C1. The substrate units 10 are arranged side by side but spaced apart from one another with gaps there-between, and the substrate units 10 may be arranged as an array on the carrier C1. Then, a molding material (not shown) fills the gaps between the substrate units 10 before performing subsequently processes.

Referring to FIG. 1D, FIG. 1D is a cross-sectional view of FIG. 1C. The substrate unit 10 (only one substrate unit is shown) is disposed on the carrier C1 and adhered (attached) onto the carrier C1 through a temporary bonding layer 91 formed on the carrier C1. In some embodiments, the temporary bonding layer 91 includes a release layer for facilitating the removal of the carrier C1 in the subsequent process steps. The carrier C1 includes a glass plate, a metal plate, a plastic supporting board or the like, or any other suitable supportive materials may be used as long as the materials are able to withstand the subsequent steps of the process.

Referring to FIG. 1E, a core structure 10′ is formed on the temporary bonding layer 91. In some embodiments, the formation of the core structure 10′ includes performing a thinning process on a surface of the substrate unit 10. The thinning process is performed until the ends of the metallic vias 115 are exposed and the metallic vias 115 become through semiconductor vias (TSVs). For example, the thinning process includes performing an etching process, a grinding process or a chemical mechanical polishing (CMP) process. In some embodiments, the core structure 10′ includes the TSVs 115 penetrating through and revealed from the semiconductor substrate 110, and the electronic component 88 disposed on a surface of the semiconductor substrate 110 and beside the TSVs 115. In some embodiments, a thickness of the TSV 115 is in a range of about 50 μm to 700 μm.

In some embodiments, a first film stack structure 120 is formed on the core structure 10′ and electrically connected with the TSVs 115. In some embodiments, the first film stack structure 120 includes a stack of insulating sublayers 122, metal wiring layers 124 and vias 125. For example, the metal wiring layers 124 includes metal routing lines, pads or contacts, and the metal wiring layer(s) 124 and the via(s) 125 that are embedded in the corresponding insulating sublayer(s) 122 are electrically interconnected to provide electrical connection for the first film stack structure 120. In some embodiments, the bottommost metal wiring layer 1242 or the bottommost vias of the first film stack structure 120 is in contact with the TSVs 115. In some embodiments, the first film stack structure 120 includes contact pads 1246 on the topmost insulating sublayer 122 for an external connection.

In some embodiments, the insulating sublayers 122 are formed from a material selected from polyimide (PI), benzocyclobutene (BCB), polybenzooxazole (PBO), or any other suitable polymer-based dielectric material including Ajinomoto build-up film (ABF), or combinations thereof. In some embodiments, the formation of the insulating sublayers includes using coating process, deposition process, lamination process, or any other suitable technique. In some embodiments, the insulating sublayers 122 are build-up sublayers. In some embodiments, the material of the metal wiring layers 124 and the vias 125 may include copper, aluminum, silver, or the like, and the metal wiring layers 124 and the vias 125 may be formed by plating processes, including electroplating, or electroless plating. In some embodiments, the metal wiring layers 124 and the vias 125 formed in the first film stack structure 120 may be formed with patterns and configuration to facilitate routing of power and transmission of input/output (I/O) signals, and to route signals and power through the semiconductor package. It should be noted that the numbers of the through vias, sublayers, patterns are merely exemplary from the perspective of the manufacturing process and not intended to limit the scope of this disclosure. For example, the first film stack structure 120 may constitute more or less sublayers, and the number and thickness of each insulating sublayer may be adjusted according to design requirement.

Referring to FIG. 1F, the carrier C1 is detached along with the removal of the temporary bonding layer 91. A structure of FIG. 1E is flipped, and the first film stack structure 120 is attached to a carrier C2 through a temporary bonding layer 92. For example, the carrier C2 and the temporary bonding layer 92 may be formed by using the same materials and the same processes used for forming the carrier C1 and the temporary bonding layer 91 as described previously.

In some embodiments, a second film stack structure 130 is formed on the core structure 10′ opposite to the first film stack structure 120, and formed on and in direct contact with the electronic components 88. In other embodiments, the second film stack structure 130 may be formed on, in direct contact with and electrically connected to the electronic components 88. In some embodiments, the second film stack structure 130 is electrically connected to the first film stack structure 120 through the TSVs 115. In some embodiments, the second film stack structure 130 includes a stack of insulating sublayers 132, metal wiring layers 134 and vias 135. For example, the metal wiring layers 134 include metal routing lines, pads or contacts, and the metal wiring layer(s) 134 and the via(s) 135 that are embedded in the corresponding insulating sublayer(s) 132 are electrically interconnected to provide electrical connection for the second film stack structure 130. In some embodiments, the bottommost metal wiring layer 1342 or the bottommost vias of the second film stack structure 130 is in contact with the TSVs 115. In some embodiments, the second film stack structure 130 includes contact pads 1346 on the topmost insulating sublayer 132 for further connection. For example, the insulating sublayers 132, the metal wiring layers 134, the vias 135 and contact pads 1346 may be formed by using the same materials and the same processes used for forming the insulating sublayers 122, the metal wiring layers 124, the vias 125 and the contact pads 1246 as described previously. In FIG. 1F, the first and the second film stack structures 120, 130 are shown to have the same number of insulating sublayers. In some alternative embodiments, the number of insulating sublayers on either side of the core structure 10′ may be different.

In some embodiments, a circuit substrate 200 is formed after the carrier C2 is detached along with the removal of the temporary bonding layer 92. The circuit substrate 200 includes the core structure 10′, the first film stack structure 120 disposed on the first surface of the core structure 10′, and the second film stack structure 130 disposed on the second surface of the core structure 10'. The second surface of the core structure 10′ is opposite to the first surface of the core structure 10′. In some embodiments, a pitch between the contact pads 1246 of the circuit substrate 200 is in a range of about greater than 100 μm. In some embodiments, a coefficient of thermal expansion (CTE) of the semiconductor substrate 110 (including Si) of the core structure 10′ is in a range of about 140 W/mK to about 170 W/mK. In some embodiments, the semiconductor substrate 110 (including Si) of the core structure 10′ improves heat dissipation. In some embodiments, a circuit substrate 200 is applied to a semiconductor package such as a chip-on-wafer-on-substrate (CoWoS) package, an integrated fan-out (InFO) package, or the like.

FIG. 1G is a schematic cross-sectional view a package structure in accordance with some embodiments of the present disclosure.

Referring to FIG. 1G, one or more package units 12 (only one is shown) are mounted onto and connected to the second film stack structure 130 of the circuit substrate 200. In some embodiments, the semiconductor package includes or is a chip-on-wafer-on-substrate (CoWoS) package, and the package unit 12 is bonded to and electrically connected with the circuit substrate 200 through electrical connectors 109. In some other embodiments, the semiconductor package may be an integrated fan-out (InFO) package or any suitable package including the circuit substrate 200. In some other embodiments, contact pads 1105 of an interposer 11 of the package unit 12 are bonded to the contact pads 1346 of the circuit substrate 200 through electrical connectors 109. In some embodiments, the electrical connectors 109 disposed between the contact pads 1105 of the package unit 12 and the contact pads 1346 of the circuit substrate 200 include or are controlled collapse chip connection (C4) bumps. In some embodiments, an underfill 107 is disposed between the package unit 12 and the circuit substrate 200 to protect the electrical connectors 109 from thermal and mechanical stresses and securing the package unit 12. In some embodiments, connective terminals 25 are formed on the contact pads 1246 of the circuit substrate 200 for further electrical connection. In some embodiments, the connective terminals 25 are solder balls for ball grid array (BGA) mounts. In some embodiments, the connective terminals 25 are electrically connected to the package unit 12 through the circuit substrate 200. In some embodiments, electrical devices may be disposed on the circuit substrate 200 through surface mount technology (SMT).

In some embodiments, the package unit 12 includes three semiconductor dies or more, and one semiconductor die 102 and two semiconductor dies 104 are shown in the cross-sectional view of the figure as an example. In some embodiments, the semiconductor dies 102, 104 may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die, or an application processor (AP) die. In some embodiments, the semiconductor die 102 includes or is a SoC die and the semiconductor dies 104 include or are HBM dies. The disclosure is not limited by the types of dies included in the package unit 12.

In some embodiments, the semiconductor dies 102, 104 are disposed with active surfaces facing the interposer 11, and are bonded to a first redistribution layer 106 of the interposer 11. In some embodiments, the semiconductor dies 102, 104 are electrically connected to the first redistribution layer 106 of the interposer 11. In some embodiments, contact pads 1043 of the semiconductor dies 102, 104 are bonded to contact pads of the first redistribution layer 106 through micro-connectors 1045.

In some embodiments, the interposer 11 includes a molding layer 108, through semiconductor vias (TSVs) 1083 penetrating the molding layer 108 for dual-side electrical connection, local silicon interconnect (LSI) dies 20 wrapped around by the molding layer 108 for connecting the semiconductor die 102 to the semiconductor dies 104, the first redistribution layer 106 disposed on a first surface of the molding layer 108, and a second redistribution layer 111 disposed on a second surface of the molding layer 108. The second surface of the molding layer 108 is opposite to the first surface of the molding layer 108. The second redistribution layer 111 includes the contact pads 1105 bonded to the contact pads 1346 of the circuit substrate 200 through electrical connectors 109. In some embodiments, a material of the TSVs 1083 includes one or more metal material such as copper, titanium, tungsten, aluminum, combinations thereof, or the like. In some embodiments, the TSVs 1083, the semiconductor dies 102, 104 are electrically connected to the circuit substrate 200 through the electrical connectors 109 located between the interposer 11 and the circuit substrate 200. In other embodiments, the interposer 11 is a silicon interposer including a silicon layer penetrating by the TSVs 1083 and a first redistribution layer disposed on the silicon layer. The silicon interposer may further include a second redistribution layer disposed on the silicon layer opposite to the first redistribution layer.

In some embodiments, after the semiconductor dies 102, 104 are bonded to the first redistribution layer 106, an underfill 103 is formed between the semiconductor dies 102, 104 and the first redistribution layer 106 surrounding the micro-connectors 1045 to protect the micro-connectors 1045 against thermal or physical stresses and secure the electrical connection of the semiconductor dies 102, 104 to the interposer 11. In some embodiments, the underfill 103 is formed by capillary underfill filling (CUF). In some embodiments, as shown in FIG. 1G, the underfill 103 is formed into multiple underfill portions with each portion respectively securing the semiconductor die 102 or 104 and the corresponding micro-connectors 1045. In some alternative embodiments, a single common underfill (not shown) may extend below the semiconductor dies 102, 104, depending on the spacing and relative positions of the dies over the interposer.

In some embodiments, an encapsulant 105 is formed over the first redistribution layer 106 of the interposer 11, wraps the semiconductor dies 102, 104, and wraps the underfill 103. In some embodiments, the encapsulant 105 laterally encapsulates the semiconductor dies 102, 104, leaving backside surfaces of the semiconductor dies 102, 104 exposed. In some embodiments, the encapsulant 105 includes a molding compound, a resin (such as epoxy resin or phenolic resin), or the like.

In FIG. 1G, only one package unit 12 with three semiconductor dies 102, 104 are shown on the interposer 11 for simplicity, but the disclosure is not limited thereto. Furthermore, whilst the process is currently being illustrated for a chip-on-wafer-on-substrate (CoWoS) package, the disclosure is not limited to the package structure shown in the drawings, and other types of semiconductor package such as integrated fan-out (InFO) packages, package-on-packages (PoP), etc., are also meant to be covered by the present disclosure and to fall within the scope of the appended claims.

In some embodiments, a thermal interface material (TIM) 320 is disposed on the package unit 12, an adhesive 330 is formed on the circuit substrate 200 and surrounds the package unit 12, and a lid 340 is disposed on the TIM 320 and the adhesive 330. In some embodiments, the lid 340 is adhered to the package unit 12 through the TIM 320 and adhered to the circuit substrate 200 through the adhesive 330.

In some embodiments, the TIM 320 includes or is a solid type metal-TIM, a liquid type metal-TIM, a gel-type TIM (containing polymer base materials) or a film-type TIM (containing polymer base materials). In some embodiments, the TIM 320 includes one or more metals from tin (Sn), gallium (Ga), indium (In), bismuth (Bi), zinc (Zn), silver (Ag) or other suitable thermally conductive metals. In some embodiments, the TIM 320 includes gallium, gallium alloys, gallium-indium-tin alloys, gallium-indium-tin-zinc alloys, indium-bismuth-tin alloys. According to the type of material used, the TIM 320 may be formed by deposition, lamination, printing, plating, or any other suitable technique. In some embodiments, the TIM 320 disposed on the backside surface of the package unit 12 further improves heat dissipation.

In some embodiments, the material of the adhesive 330 is independently selected from a thermo-curable adhesive, a photocurable adhesive, a thermally conductive adhesive, a thermosetting resin, a waterproof adhesive, a lamination adhesive, or a combination thereof. According to the type of material(s) used, the adhesive 330 may be formed by dispensing, lamination, printing, or any other suitable technique.

In some embodiments, the lid 340 includes a horizontal portion extending on the TIM 320 and the package unit 12, and a vertical portion joined with the horizontal portion and surrounding the horizontal portion. In some embodiments, the horizontal portion is disposed directly on the TIM 320 and fully covers the TIM 320 and extends substantially parallel to the circuit substrate 200. In some embodiments, the vertical portion extends in a direction substantially perpendicular to the plane defined by the horizontal portion. In some embodiments, the horizontal portion and the vertical portion are integrally formed (i.e. jointed to each other without a clear interface between the two).

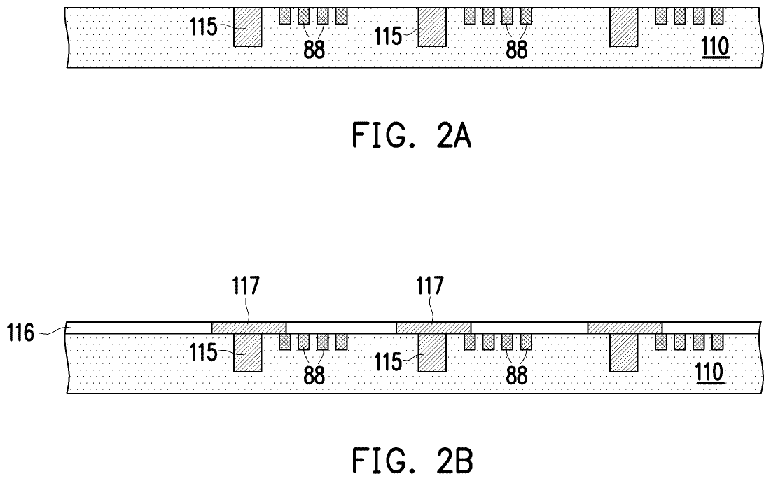

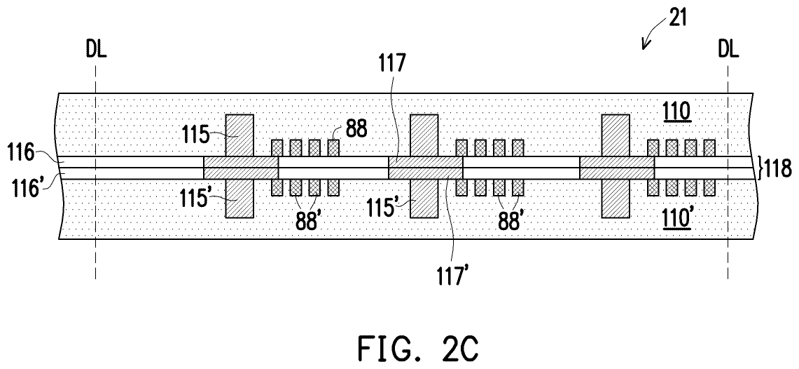

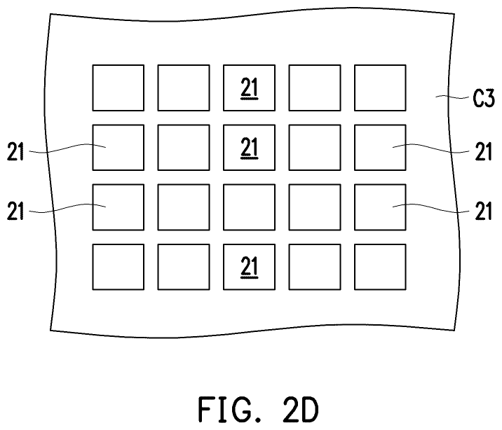

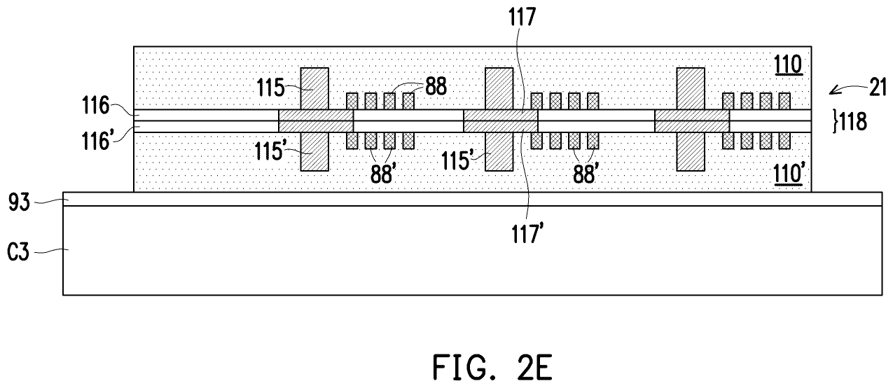

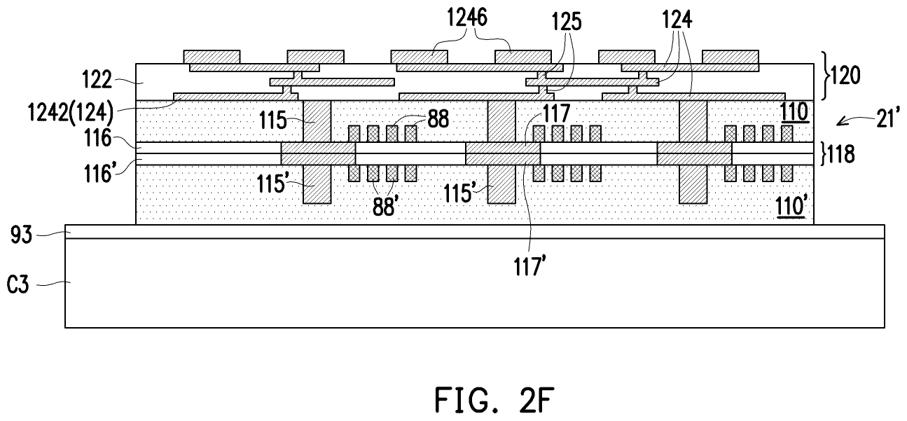

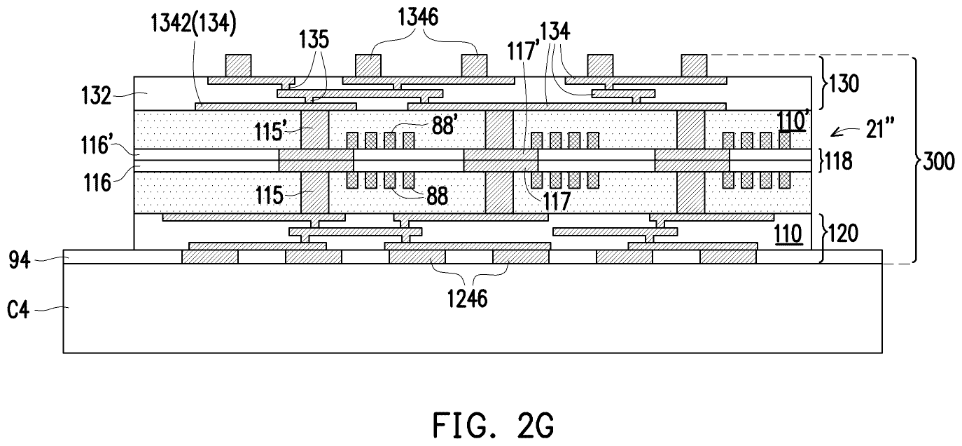

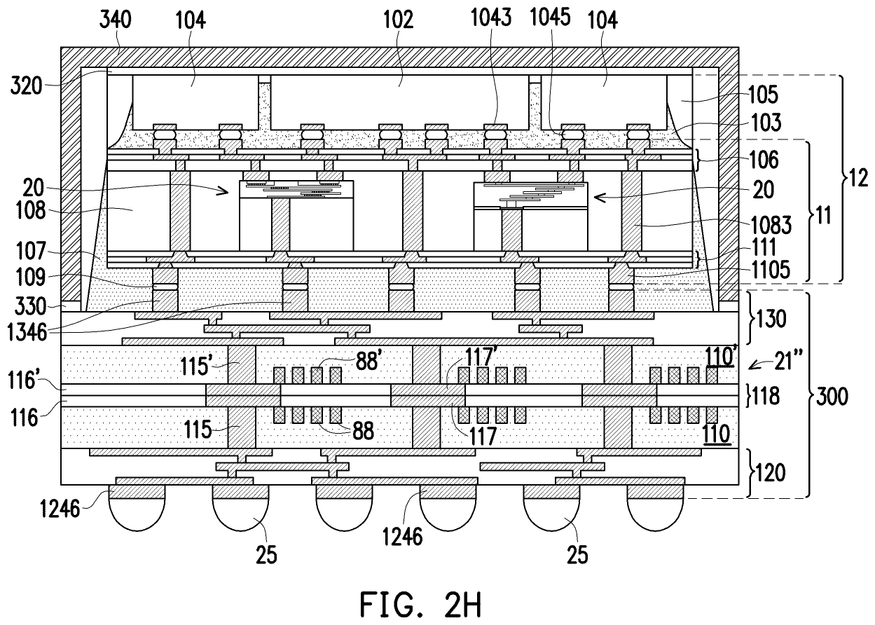

FIG. 2A to FIG. 2G are schematic cross-sectional views and top views of stages in a formation method of a circuit substrate in accordance with some embodiments of the present disclosure. Except for the further description, the definition of the reference symbols and labeled representations are the same as FIG. 1A through FIG. 1F, and will not be repeated herein.

Referring to FIG. 2A, the difference from FIG. 1B is that a singulation process is not performed yet after the formation of the metallic vias 115. Referring to FIG. 2B, a dielectric layer 116 is formed on the semiconductor substrate 110, the metallic vias 115 and the electronic component 88. For example, a material of the dielectric layer 116 includes a dielectric material, such as silicon oxide (SiO₂) or any suitable dielectric material. In some embodiments, the dielectric layer 116 is formed by using chemical vapor deposition (CVD), physical vapor deposition (PVD), or the like. In some embodiments, openings (not shown) are formed in the dielectric layer 116 by using any suitable etching processes. In some embodiments, bonding pads 117 are formed, after a metal material is formed in and fills the openings of the dielectric layer 116. For example, a material of the bonding pads 117 includes metal such as copper or any suitable materials. In some embodiments, the bonding pads 117 are formed by using any suitable techniques such as plating processes, chemical vapor deposition (CVD), or the like. In some embodiments, top surfaces of the bonding pads 117 are levelled with a top surface of the dielectric layer 116.

Referring to FIG. 2C, the dielectric layer 116 and the bonding pads 117 of one structure of FIG. 2B (referred to as an upper structure) are bonded to the dielectric layer (referred to as dielectric layer 116′) and the bonding pads (referred to as bonding pads 117′) of another structure of FIG. 2B (referred to as a lower structure) through hybrid-bonding. The lower structure further includes the semiconductor substrate (referred to as a semiconductor substrate 110′), the metallic vias (referred to as metallic vias 115′) and the electronic components (referred to as electronic components 88′). In some embodiments, after performing a bonding process, a bonding layer 118 is formed, and sandwiched between the semiconductor substrate 110 and the semiconductor substrate 110′, between the metallic vias 115 and the metallic vias 115′, and between the electronic components 88 and the electronic components 88′. In some embodiments, the bonding layer 118 includes a dielectric portion including the dielectric layers 116, 116′, and a metal portion including the bonding pads 117, 117′. In some embodiments, the dielectric portion of the bonding layer 118 is sandwiched between the semiconductor substrates 110, 110′ and the electronic components 88, 88′. In some embodiments, the metal portion is disposed within the dielectric portion and sandwiched between the metallic vias 115, 115′. In some embodiments, the metal portion is in contact with and electrically connected to the metallic vias 115, 115′.

In some embodiments, the formation of the hybrid-bonding includes performing an annealing process. In some embodiments, the bonding pads 117 formed on the semiconductor substrate 110 are bonded to the bonding pads 117′ formed on the semiconductor substrate 110′ through metal-to-metal bonding. In some embodiments, the dielectric layer 116 formed on the semiconductor substrate 110 is bonded to the dielectric layer 116′ formed on the semiconductor substrate 110′ through dielectric-to-dielectric bonding. After the formation of the hybrid-bonding, a singulation process is performed to the two semiconductor substrates 110, 110′ (in wafer form), cutting through the two semiconductor substrates 110, 110′. In some embodiments, the singulation process includes performing a wafer dicing process cutting along dicing lines DL to form substrate units 21, as shown in FIG. 2D.

Referring to FIG. 2D, FIG. 2D is a top view. The substrate units 21 are provided and disposed on a carrier C3. The substrate units 21 are arranged side by side but spaced apart from one another with gaps there-between, and the substrate units 21 may be arranged as an array on the carrier C3. Then, a molding material (not shown) fills the gaps between the substrate units 21 before performing subsequently processes.

Referring to FIG. 2E, FIG. 2E is a cross-sectional view of FIG. 2D. The substrate unit 21 (only one substrate unit is shown) is disposed on the carrier C3 and adhered (attached) onto the carrier C3 through a temporary bonding layer 93 formed on the carrier C3. In some embodiments, the temporary bonding layer 93 includes a release layer for facilitating the removal of the carrier C3 in the subsequent process steps. For example, the carrier C3 and the temporary bonding layer 93 may be formed by using the same materials and the same processes used for forming the carrier C1 and the temporary bonding layer 91 as described previously.

Referring to FIG. 2F, a substrate unit 21′ is formed on the temporary bonding layer 93. In some embodiments, the formation of the substrate unit 21′ includes performing a thinning process on a surface of the semiconductor substrate 110 of the substrate unit 21 by using the same process used for forming the core structure 10′ as described previously. The thinning process is performed until the ends of the metallic vias 115 are exposed and the metallic vias 115 become through semiconductor vias (TSVs). In some embodiments, the first film stack structure 120 is formed on the substrate unit 21′.

Referring to FIG. 2G, the carrier C3 is detached along with the removal of the temporary bonding layer 93. A structure of FIG. 2F is flipped, and the first film stack structure 120 is attached to a carrier C4 through a temporary bonding layer 94. For example, the carrier C4 and the temporary bonding layer 94 may be formed by using the same materials and the same processes used for forming the carrier C1 and the temporary bonding layer 91 as described previously.

In some embodiments, a core structure 21″ is formed on the temporary bonding layer 94. In some embodiments, the formation of the core structure 21″ includes performing a thinning process on a surface of the semiconductor substrate 110′ of the substrate unit 21′ by using the same process used for forming the core structure 10′ as described previously. The thinning process is performed until the ends of the metallic vias 115′ are exposed and the metallic vias 115′ become through semiconductor vias (TSVs). In some embodiments, the second film stack structure 130 is formed on the core structure 21″ opposite to the first film stack structure 120.

In some embodiments, the core structure 21″ is disposed between the first and second film stack structures 120, 130. The core structure 21″ includes the semiconductor substrate 110 having TSVs 115 penetrating through the semiconductor substrate 110, the semiconductor substrate 110′ having TSVs 115′ penetrating through the semiconductor substrate 110′. In some embodiments, the semiconductor substrate 110 is bonded to the semiconductor substrate′ through the bonding layer 118. In some embodiments, the first film stack structure 120 is electrically connected to the second film stack structure 130 through the TSVs 115, 115′ and the bonding pads 117, 117′. In some embodiments, the electronic components 88, 88′ are respectively disposed on the bonding layer 118, and electrically connected to the first and second film stack structures 120, 130. In other embodiments, the core structure 21″ may constitute more than two of the semiconductor substrates according to design requirement. In some embodiments, a thickness of the core structure 21″ is in a range of about 700 μm to about 1400 μm.

In some embodiments, a circuit substrate 300 is formed after the carrier C4 is detached along with the removal of the temporary bonding layer 94. The circuit substrate 300 includes the core structure 21″, the first film stack structure 120 disposed on the first surface of the core structure 21″, and the second film stack structure 130 disposed on the second surface of the core structure 21″. The second surface of the core structure 21″ is opposite to the first surface of the core structure 21″. In some embodiments, a pitch between the contact pads 1246 of the circuit substrate 300 is in a range of about greater than 100 μm. In some embodiments, a coefficient of thermal expansion (CTE) of the semiconductor substrates 110, 110′ (including Si) of the core structure 21″ is in a range of about 140 W/mK to about 170 W/mK. In some embodiments, the semiconductor substrates 110, 110′ (including Si) of the core structure 21″ improve heat dissipation. In some embodiments, a circuit substrate 300 is applied to a semiconductor package such as a chip-on-wafer-on-substrate (CoWoS) package, an integrated fan-out (InFO) package, or the like.

FIG. 2H is a schematic cross-sectional view a package structure in accordance with some embodiments of the present disclosure. The difference from FIG. 1G is the circuit substrate 300 instead of the circuit substrate 200.

Referring to FIG. 2H, one or more package units 12 (only one is shown) are mounted onto and connected to the second film stack structure 130 of the circuit substrate 300. In some embodiments, the semiconductor package includes or is a chip-on-wafer-on-substrate (CoWoS) package, and the package unit 12 is bonded to and electrically connected with the circuit substrate 300 through electrical connectors 109. In some other embodiments, the semiconductor package may be an integrated fan-out (InFO) package or any suitable package including the circuit substrate 300. In some other embodiments, contact pads 1105 of an interposer 11 of the package unit 12 are bonded to the contact pads 1346 of the circuit substrate 300 through electrical connectors 109. In some embodiments, the electrical connectors 109 disposed between the contact pads 1105 of the package unit 12 and the contact pads 1346 of the circuit substrate 300 include or are controlled collapse chip connection (C4) bumps. In some embodiments, the connective terminals 25 are formed on the contact pads 1246 of the circuit substrate 300 for further electrical connection. In some embodiments, the connective terminals 25 are solder balls for ball grid array (BGA) mounts. In some embodiments, the connective terminals 25 are electrically connected to the package unit 12 through the circuit substrate 300. In some embodiments, electrical devices may be disposed on the circuit substrate 300 through surface mount technology (SMT).

Furthermore, whilst the process is currently being illustrated for a chip-on-wafer-on-substrate (CoWoS) package, the disclosure is not limited to the package structure shown in the drawings, and other types of semiconductor package such as integrated fan-out (InFO) packages, package-on-packages (PoP), etc., are also meant to be covered by the present disclosure and to fall within the scope of the appended claims.

A package structure and a method of forming the package structure are provided. The package structure includes a circuit substrate including a core structure sandwiched between first and second film stack structures. The core structure includes a semiconductor substrate (e.g. a silicon-containing semiconductor substrate) penetrated by through semiconductor vias (TSVs). The package structure is supported by the thinner core structure with the excellent mechanical properties of the semiconductor substrate. The thinner core structure is beneficial to the electrical performance such as the Power Delivery Network (PDN) performance. Also, the semiconductor substrate improves the heat dissipation of the package structure. As a result, the reliability of the circuit substrate is improved. Further, passive devices fabricated in the semiconductor substrate improves both the signal integrity and the power integrity.

In accordance with some embodiments of the present disclosure, a package structure is provided. The package structure includes a circuit substrate, an interposer disposed on and electrically connected the circuit substrate, and a die disposed on the interposer and electrically connected to the circuit substrate through the interposer. The circuit substrate includes a first film stack structure, a second film stack structure disposed on the first film stack structure, and a core structure disposed between the first and second film stack structures. The core structure includes a first semiconductor substrate having first through semiconductor vias (TSVs). The first TSVs penetrate through the first semiconductor substrate and are electrically connected to the first and second film stack structures. The interposer is disposed on and electrically connected to the second film stack structure of the circuit substrate.

In accordance with some embodiments of the present disclosure, a package structure is provided. The package structure includes a circuit substrate, and a die disposed on and electrically connected to the circuit substrate. The circuit substrate includes a core structure, and first and second film stack structures disposed respectively on two opposite sides of the core structure. The core structure includes a first silicon-containing semiconductor substrate penetrated by first through semiconductor vias (TSVs), and a first passive device disposed in the first silicon-containing semiconductor substrate and beside the first TSVs. The first TSVs are electrically connected to the first and second film stack structures. The die is electrically connected to the circuit substrate through the second film stack structure of the circuit substrate.

In accordance with some embodiments of the present disclosure, a method of forming a package structure is provided. First through semiconductor vias (TSVs) are formed in a first semiconductor substrate. The first TSVs penetrate through the first semiconductor substrate. A first film stack structure is formed on a first surface of the first semiconductor substrate. A second film stack structure is formed on a second surface of the first semiconductor substrate, thereby forming a core structure. The second surface of the first semiconductor substrate is opposite to the first surface of the first semiconductor substrate. The core structure includes the first and second film stack structures, and the first semiconductor substrate electrically connected to the first and second film stack structures through the first TSVs. An interposer is bonded to the second film stack structure of the circuit substrate. A die is bonded to the interposer. The die is electrically connected to the circuit substrate through the interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate comprising:
a first film stack structure,
a second film stack structure disposed on the first film stack structure, and
a core structure disposed between the first and second film stack structures, wherein the core structure comprises a first semiconductor substrate having first through semiconductor vias (TSVs), and wherein the first TSVs penetrate through the first semiconductor substrate and are electrically connected to the first and second film stack structures;
an interposer disposed on and electrically connected to the second film stack structure of the circuit substrate; and
a die disposed on the interposer and electrically connected to the circuit substrate through the interposer.

2. The package structure of claim 1, wherein the core structure further comprises:
an electronic component disposed in the first semiconductor substrate and beside the first TSVs,
wherein the electronic component is in contact with and electrically connected to the second film stack structure.

3. The package structure of claim 2, wherein the electronic component comprises an embedded deep trench capacitor (eDTC).

4. The package structure of claim 1, wherein a material of the first semiconductor substrate comprises silicon.

5. The package structure of claim 1, wherein the core structure further comprises:
a second semiconductor substrate bonded to the first semiconductor substrate through a bonding layer, and having second TSVs penetrating through the second semiconductor substrate,
wherein the second TSVs are electrically connected to the first TSVs through the bonding layer.

6. The package structure of claim 5, wherein the bonding layer further comprises:
a dielectric portion sandwiched between the first and second semiconductor substrates, and
a metal portion disposed within the dielectric portion and sandwiched between the first and second TSVs, in contact with and electrically connected to the first and second TSVs.

7. The package structure of claim 5, wherein the core structure further comprises:
a first electronic component disposed in the first semiconductor substrate, beside the first TSVs, and
a second electronic component disposed in the second semiconductor substrate, beside the second TSVs,
wherein the bonding layer is sandwiched between the first and second TSVs and between the first and second electronic components.

8. The package structure of claim 1, wherein the interposer comprises a silicon interposer.

9. The package structure of claim 1, further comprising:
connective terminals disposed on contact pads on a surface of the first film stack structure of the circuit substrate, wherein the connective terminals are solder balls for ball grid array (BGA) mounts.

10. A package structure, comprising:
a circuit substrate comprising:
a core structure, and
first and second film stack structures disposed respectively on two opposite sides of the core structure,
wherein the core structure comprises a first silicon-containing semiconductor substrate, and a first passive device disposed in the first silicon-containing semiconductor substrate ; and
a die disposed on and electrically connected to the circuit substrate through the second film stack structure of the circuit substrate.

11. The package structure of claim 10, wherein the first silicon-containing semiconductor substrate is penetrated by first through semiconductor vias (TSVs) that are electrically connected to the first and second film stack structures,
wherein the first passive device is disposed beside the first TSVs, and
wherein the core structure further comprises:
a second silicon-containing semiconductor substrate bonded to the first silicon-containing semiconductor substrate through a bonding layer, and having second TSVs penetrating through the second silicon-containing semiconductor substrate, wherein the second TSVs are electrically connected to the first TSVs through the bonding layer.

12. The package structure of claim 11, wherein the bonding layer further comprises:
a dielectric portion sandwiched between the first and second silicon-containing semiconductor substrates, and
a metal portion disposed within the dielectric portion and sandwiched between the first and second TSVs, in contact with and electrically connected to the first and second TSVs.

13. The package structure of claim 11, wherein the core structure further comprises:
a second passive device disposed in the second silicon-containing semiconductor substrate, beside the second TSVs,
wherein the bonding layer is sandwiched between the first and second TSVs and between the first and second passive devices.

14. The package structure of claim 10, further comprising:
an interposer disposed between the die and the circuit substrate and electrically connected the die to the circuit substrate.

15. The package structure of claim 10, wherein a thickness of the core structure is in a range of about 50 μm to about 1400 μm.

16. A method of forming a package structure, comprising:
forming first through semiconductor vias (TSVs) in a first semiconductor substrate, wherein the first TSVs penetrate through the first semiconductor substrate;
forming a first film stack structure on a first surface of the first semiconductor substrate,
forming a second film stack structure on a second surface of the first semiconductor substrate, thereby forming a core structure including the first and second film stack structures and the first semiconductor substrate electrically connected to the first and second film stack structures through the first TSVs, wherein the second surface of the first semiconductor substrate is opposite to the first surface of the first semiconductor substrate;
bonding an interposer to the second film stack structure of the circuit substrate; and
bonding a die to the interposer, wherein the die is electrically connected to the circuit substrate through the interposer.

17. The method of claim 16, further comprising:
forming an electronic component in the first semiconductor substrate and beside the first TSVs,
wherein the electronic component is electrically connected to the second film stack structure.

18. The method of claim 17, wherein the electronic component comprises an embedded deep trench capacitor (eDTC).

19. The method of claim 16, wherein a material of the first semiconductor substrate includes silicon.

20. The method of claim 16, further comprising:
forming second through semiconductor vias (TSVs) in a second semiconductor substrate, wherein the second TSVs penetrate through the second semiconductor substrate; and
bonding the second semiconductor substrate to the first semiconductor substrate, thereby forming the core structure including the first and second film stack structures and the first and second semiconductor substrate sandwiched between the first and second film stack structures.
